(19) United States
(12) Patent Application Publication
(10) Pub. No.: US 2025/0357380 A1
(43) Pub. Date: Nov. 20, 2025

(54) SEMICONDUCTOR PACKAGE DEVICE AND METHOD OF FORMING THE SAME

(71) Applicant: Winbond Electronics Corp., Taochung CIty (TW)

(72) Inventor: Yung-Fu CHANG, Kaohsiung City (TW)

(21) Appl. No.: 18/804,312

(22) Filed: Aug. 14, 2024

(30) Foreign Application Priority Data
May 17, 2024 (TW) 113118367

(51) Int. Cl. H01L 23/58; H01L 21/768; H01L 21/78; H01L 23/00; H01L 23/48; H01L 25/065

(52) U.S. Cl. CPC H01L 23/585; H01L 21/76898; H01L 21/78; H01L 23/481; H01L 24/05; H01L 24/11; H01L 24/32; H01L 24/73; H01L 25/0657; H01L 2224/0557; H01L 2224/16145; H01L 2224/32225; H01L 2224/73204; H01L 2225/06541; H01L 2924/15311

(57) ABSTRACT

A semiconductor package device includes a carrier and a first chip stack disposed on the carrier. The first chip stack includes a first chip in contact with the carrier, and a second chip disposed on the first chip. The first chip includes a first through silicon via disposed on a sidewall of the first chip, and the second chip includes a second through silicon via disposed on a sidewall of the second chip. The semiconductor package device further includes a first conductive layer extended from a surface of the first through silicon via to a surface of the second through silicon via. The first conductive layer electrically connects the first chip to the second chip.

### CROSS REFERENCE TO RELATED APPLICATIONS

This application claims priority of Taiwan Patent Application No. 113118367, filed May 17, 2024, the entirety of which is incorporated by reference herein.

### BACKGROUND

### Technical Field

The present disclosure relates to a semiconductor package device and method of forming the same, and in particular, to a through silicon via (TSV) and method of forming the same.

### Description of the Related Art

In order to stack one chip over another chip and to establish electrical connection, the grinding may usually be performed on the backside of the substrate to expose the through silicon vias formed within the substrate. In the package process, when the vertically stacked chips are bonded to the carrier, the area of the carrier being occupied may be conserved (for example, only need to consume the area for the dynamic random access memory (DRAM)), which in turn realizes the package device with higher functional density. However, these procedures require high cost and long cycle time. Thus, there remain some issues regarding the semiconductor package device and manufacturing technique that need to be overcame.

### SUMMARY

An embodiment of the present disclosure provides a semiconductor package device, the semiconductor package device includes: a carrier; and a first chip stack disposed on the carrier. The first chip stack includes: a first chip in contact with the carrier; and a second chip disposed on the first chip. The first chip includes a first through silicon via disposed on a sidewall of the first chip, and the second chip includes a second through silicon via disposed on a sidewall of the second chip. The semiconductor package device further includes a first conductive layer extended from a surface of the first through silicon via to a surface of the second through silicon via. The first conductive layer electrically connects the first chip to the second chip.

Another embodiment of the present disclosure provides a method of forming a semiconductor package device, the method includes providing a first wafer and providing a second wafer. The first wafer includes: a first substrate; a first seal ring structure and a second seal ring structure embedded within the first substrate; first bonding pads disposed on the first substrate; and a first through silicon via and a second through silicon via embedded within the first substrate. The first seal ring structure laterally surrounds a first set of the first bonding pads, while the second seal ring structure laterally surrounds a second set of the first bonding pads. The first through silicon via and the second through silicon via are located outside the first seal ring structure and the second seal ring structure, respectively. The second wafer includes: a second substrate; a third seal ring structure and a fourth seal ring structure embedded within the second substrate; second bonding pads disposed on the second substrate; a third through silicon via and a fourth through silicon via embedded within the second substrate; and a dielectric layer covering the second bonding pads. The third seal ring structure laterally surrounds a first set of the second bonding pads, while the fourth seal ring structure laterally surrounds a second set of the second bonding pads. The third through silicon via and the fourth through silicon via are located outside the third seal ring structure and the fourth seal ring structure, respectively. The method further includes: performing a singulation process on the first wafer to form a first chip and a second chip, wherein the first through silicon via and the second through silicon via are exposed from a sidewall of the first chip and a sidewall of the second chip, respectively; and performing the singulation process on the second wafer to form a third chip and a fourth chip, wherein the third through silicon via and the fourth through silicon via are exposed from a sidewall of the third chip and a sidewall of the fourth chip, respectively. The method further includes: sequentially stacking the first chip and the third chip on a carrier; sequentially stacking the second chip and the fourth chip on the carrier; forming a first conductive layer to electrically connect the first through silicon via of the first chip to the third through silicon via of the third chip; and forming a second conductive layer to electrically connect the second through silicon via of the second chip to the fourth through silicon via of the fourth chip.

### BRIEF DESCRIPTION OF THE DRAWINGS

FIGS. 1-11 illustrate cross-sectional views of various intermediate stages of forming a semiconductor package device, according to some embodiments of the present disclosure.

### DETAILED DESCRIPTION

The semiconductor package device of the present disclosure illustrates an innovative design of through silicon vias with a conductive layer. Instead of disposing through silicon vias inside the circuit area of a chip and combining them with bump structures and bump pads, through silicon vias may be formed on the sidewall of the chip (or outside the circuit area), and the process of manufacturing the bump structures and the bump pads may be omitted. Since the chip is formed by performing a singulation process on the wafer, the location of the through silicon vias corresponds to the dicing streets (or the scribe lines) of the wafer. After the vertical stack of multiple chips is completed, the conductive material may be grown on the exposed surface of the through silicon vias on the sidewall of every chip. As the growth duration progresses, the conductive material may be expanded in a vertical direction, which allows the conductive material on the through silicon vias of every chip to be adjoined with each other, and the electrical connection between the overlying chip and the underlying chip may be established. The cost and the cycle time of the semiconductor package device may be improved, and the performance of the semiconductor package device may be enhanced.

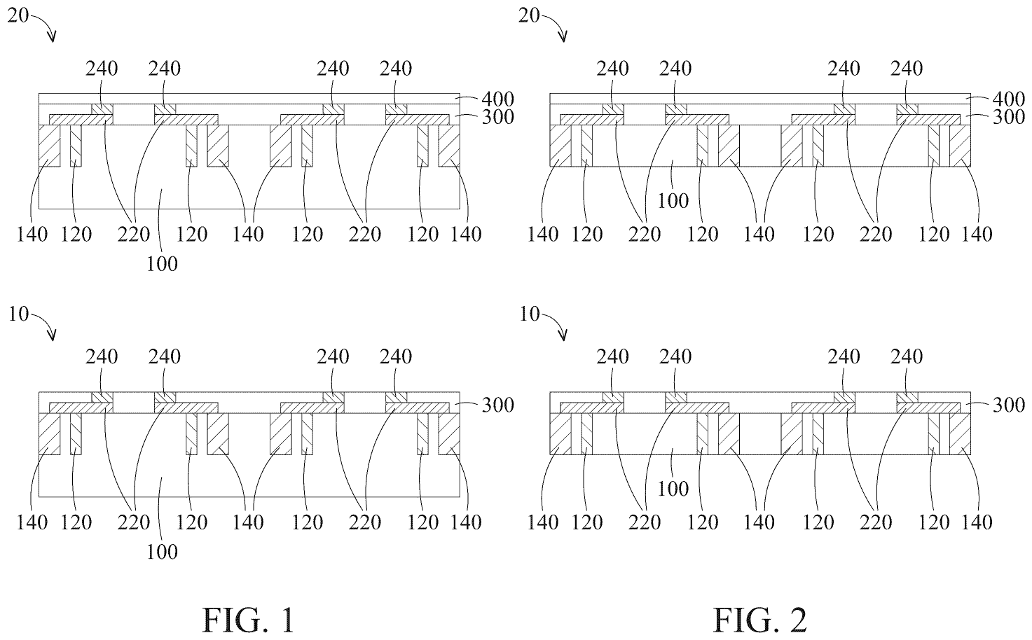

FIGS. 1-8 illustrate cross-sectional views of various intermediate stages of forming a semiconductor package device 1000. The semiconductor package device 1000 may include chip stacks formed from different wafers, and the illustrative wafers only show a portion of the circuit structure.

Referring to FIG. 1, a wafer 10 and a wafer 20 may first be provided. The initial structure of each of the wafer 10 and the wafer 20 may include a substrate 100, seal ring structures 120, through silicon vias 140, wiring layers 220, bonding pads 240, and a passivation layer 300. In comparison with the wafer 10, the wafer 20 additionally includes a dielectric layer 400. The wafer 20 (or the subsequently formed chips from the wafer 20) may be set as the topmost elements of the chip stacks of the semiconductor package device 1000.

The substrate 100 may be for example a wafer or a die, but the present disclosure is not limited thereto. The substrate 100 may also be a semiconductor on insulator (SOI) substrate. The semiconductor on insulator substrate may include a base plate, a buried oxide (BOX) layer disposed on the base plate, and a semiconductor layer disposed on the buried oxide layer. For example, the buried oxide layer may be silicon dioxide (SiO₂).

The substrate 100 may include an isolation structure to define active regions and to electrically isolate active region elements within or above the substrate 100, but the present disclosure is not limited thereto. Examples of the isolation structure may include shallow trench isolation (STI) structure, deep trench isolation (DTI) structure, or local oxidation of silicon (LOCOS) structure. The formation of the isolation structure may include, for example, forming an insulating layer on the surface of the substrate 100, and selectively etching the insulating layer and the substrate 100 to form trenches that extend from the surface of the substrate 100 into the substrate 100, wherein the trenches are located between neighboring active regions. Next, the formation of the isolation structure may include growing a liner of rich nitrogen-containing materials (such as silicon oxynitride or the like) along the trenches, followed by filling insulating materials (such as silicon dioxide, silicon nitride, silicon oxynitride, or the like) into the trenches by a suitable deposition process. An annealing process may then be performed, followed by a planarization process (for example, chemical mechanical polish process) to remove excessive insulating materials, so the insulating materials in the trenches are level with the top surface of the substrate 100.

Still referring to FIG. 1, the seal ring structures 120 may be formed within the substrate 100 of each of the wafer 10 and the wafer 20. The seal ring structures 120 may each be a continuous ring structure from a top view, which laterally surrounds the circuit area of every chip being singulated subsequently. The seal ring structures 120 may be disposed along the periphery of the predetermined circuit area, and may serve as guarding elements to prevent chipping generated from the dicing process of the singulation from extending into the circuit area of the chips. In other words, the seal ring structures 120 are located between the predetermined dicing street area and the predetermined circuit area of the chips. Since each of the wafer 10 and the wafer 20 may be subsequently singulated into two chips (to be described in detail below), the wafer 10 and the wafer 20 each includes two seal ring structures 120. The width of the seal ring structures 120 from a top view may be between 4 μm and 6 μm, for example, 5 μm. Furthermore, the distance between neighboring seal ring structures 120 (that is, the dimension of the dicing street) may be between 80 μm and 150 μm.

Materials of the seal ring structures 120 may include amorphous silicon, poly-silicon, poly-germanium, poly-silicon germanium, metal nitrides (such as titanium nitride (TiN), tantalum nitride (TaN), tungsten nitride (WN), or titanium aluminum nitride (TiAIN)), metals, the like, a combination thereof, or a multiple layer thereof.

Referring to FIG. 1, the through silicon vias 140 may be formed within the substrate 100 of each of the wafer 10 and the wafer 20, and may be located outside the continuous ring structure of the seal ring structures 120. In other words, the through silicon vias 140 may be disposed at the predetermined dicing street area, instead of at the predetermined circuit area of the chips. The through silicon vias 140 may have any suitable geometrical shapes from a top view. For example, the through silicon vias 140 may be cylindrical shapes. The horizontal dimension (for example, the diameter) of the through silicon vias 140 may be between 10 μm and 20 μm. The vertical dimension (for example, the height) of the through silicon vias 140 may be between 50 μm and 150 μm. Materials and the formation of the through silicon vias 140 may be similar to those of the seal ring structures 120, and the details are not described again herein to avoid repetition. After holes are formed in the substrate 100 using the patterning process, copper may be filled into the holes to become the through silicon vias 140.

The through silicon vias 140 may be disposed at the predetermined dicing street area. During singulation, a selective dicing process may be used to partially expose the through silicon vias 140. Because it is originally required to perform the dicing process anyway, there would be no additional cost and cycle time. That is, the present disclosure implements a conductive layer (to be described in detail below) to vertically connect the through silicon vias 140 on the sidewalls of every chip after the chip stack is completed. Therefore, the original bump pads and bump structures may be omitted at the predetermined circuit area of the chips, and an adhesive layer (to be described in detail below) may be applied to carry out the vertical connection between the chips. Such configuration may also release additional space from the predetermined circuit area of the chips, allowing more components to be integrated into the chips to increase functional density. Furthermore, the additional bump structures disposed on the top surfaces of the chip stacks may not need to correspond to the location of the through silicon vias 140, thus an interposer may not need to be additionally disposed and bonded to a printed circuit board.

Still referring to FIG. 1, the wring layers 220 may be formed on the substrate 100 of each of the wafer 10 and the wafer 20. The wring layers 220 may laterally extend from the predetermined circuit area of the chips to the predetermined dicing street area, and may electrically connect the through silicon vias 140 and the subsequently formed bonding pads 240. In other words, the wiring layers 220 may span across and cover the seal ring structures 120, and may reach the through silicon vias 140. The thickness of the wiring layers 220 may be between 1 μm and 3 μm. Materials and the formation of the wiring layers 220 may be similar to those of the seal ring structures 120, and the details are not described again herein to avoid repetition.

Referring to FIG. 1, the bonding pads 240 may be formed on the substrate 100 of each of the wafer 10 and the wafer 20. The bonding pads 240 may be arranged in the predetermined circuit area of the chips, and may sit on the wiring layers 220. The seal ring structures 120 may be laterally located between the through silicon vias 140 and the bonding pads 240, and the bonding pads 240 may function as for example the wire bonding of back-end of line (BEOL). The wiring layers 220 may be vertically located between the substrate 100 and the bonding pads 240, and the wiring layers 220 may extend from below the bonding pads 240 to above the through silicon vias 140. Since the wafer 10 and the wafer 20 each includes two seal ring structures 120, the bonding pads 240 may be divided into two sets, which are laterally surrounded by the two seal ring structures 120, respectively. It should be appreciated that various active components and/or passive components may be formed in the wafer 10 and the wafer 20, not shown for simplicity. The thickness of the bonding pads 240 may be between 1 μm and 5 μm. The horizontal dimension of the bonding pads 240 may be between 50 μm×50 μm and 80 μm×80 μm from a top view, for example, having a design of 75 μm×75 μm. Materials and the formation of the bonding pads 240 may be similar to those of the seal ring structures 120, and the details are not described again herein to avoid repetition.

Still referring to FIG. 1, the passivation layer 300 may be formed on the substrate 100 of each of the wafer 10 and the wafer 20. The passivation layer 300 may cover the substrate 100, the wiring layers 220, and the bonding pads 240, and may provide the mechanical protection and the electrical insulation for the underlying structures. The thickness of the passivation layer 300 may be between 1 μm and 2 μm. Materials of the passivation layer 300 may include silicon oxide, silicon oxynitride, silicon oxycarbonitride (SiOCN), tetra ethyl ortho silicate (TEOS), undoped silicate glass, doped silicon oxide (such as boron-doped phosphosilicate glass (BPSG), fused silica glass (FSG), phosphosilicate glass (PSG), boron-doped silicate glass (BSG), or the like), low-k dielectric materials, or the like. After the planarization process, the top surface of the bonding pads 240 may be leveled with the top surface of the passivation layer 300.

Referring to FIG. 1, the dielectric layer 400 may be formed on the passivation layer 300 of the wafer 20. As mentioned previously, in order to connect the chip stack to other components (such as the printed circuit board), it is necessary to dispose bump structures 1600 (described in detail below) on the top surfaces of the chip stacks, and the dielectric layer 400 may serve as a redistribution layer (RDL) or an interlayer dielectric (ILD) connecting the bonding pads 240 to the bump structures 1600. As mentioned above, the wafer 20 (or the subsequently formed chips from the wafer 20) may be set as the topmost elements of the chip stacks of the semiconductor package device 1000, thus the wafer 20 additionally requires the dielectric layer 400. The thickness of the dielectric layer 400 may be between 1 μm and 2 μm. Materials of the dielectric layer 400 may include silicon nitride, silicon oxynitride, silicon carbonitride (SiCN), silicon oxynitrocarbide, polyimide (PI), or the like. The formation of the dielectric layer 400 may be similar to that of the passivation layer 300, and the details are not described again herein to avoid repetition.

Referring to FIG. 2, the substrate 100 of each of the wafer 10 and the wafer 20 may be thinned. Depending on the application and the design requirements, the substrate 100 may be grinded to the required thickness from the backside of the substrate 100, for example, exposing the lower surfaces of the through silicon vias 140. The substrate 100 of each of the wafer 10 and the wafer 20 may be thinned by Taiko grinding process, non-Taiko grinding process, or the like. An additional etching process may be performed after the thinning, so the grinded backside of the substrate 100 may have a more planar surface.

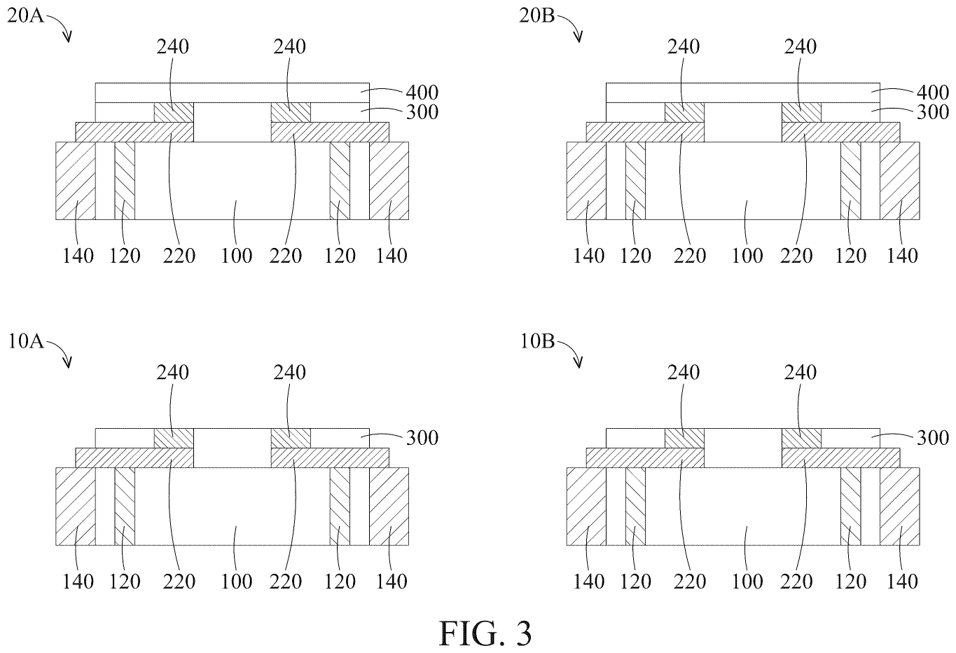

Referring to FIG. 3, a singulation process may be performed on the thinned wafer 10 and the thinned wafer 20. The singulation process for the wafer 10 and the wafer 20 may be performed by blade saw, die break dicing, laser dicing, plasma dicing, stealth dicing, or the like. For stealth dicing, multiple holes may be punched through along the dicing streets, followed by expanding the wafer to break away chips from where the multiple holes are. The singulation process may be performed using a mask with plasma dicing. Because plasma dicing is selective, thus the material of the substrate 100 (for example, silicon) may be cut in the predetermined dicing street area without substantially damaging the material of the through silicon vias 140 (for example, copper). Using the mask may further ensure the precision of the singulation process, so the portions of the cylindrical shape of the through silicon vias 140 away from the seal ring structures 120 are exposed, while the portions of the cylindrical shape of the through silicon vias 140 close to the seal ring structures 120 are still covered by the material of the substrate 100.

The wafer 10 may be singulated into a chip 10A and a chip 10B, while the wafer 20 may be singulated into a chip 20A and a chip 20B. Each of the chip 10A, the chip 10B, the chip 20A, and the chip 20B may include the substrate 100, the seal ring structure 120, through silicon vias 140, wiring layers 220, bonding pads 240, and a passivation layer 300. The seal ring structure 120 laterally surrounds the circuit area within the substrate 100. The through silicon vias 140 are located at opposite sides outside the seal ring structure 120. The wiring layers 220 extend from inside the seal ring structure 120 to outside the seal ring structure 120. The bonding pads 240 are on the wiring layers 220. The passivation layer 300 covers the wiring layers 220 and the bonding pads 240. Furthermore, the chip 20A and the chip 20B may each additionally include the dielectric layer 400 on the passivation layer 300. The through silicon vias 140 may be located on the sidewalls of each of the chip 10A, the chip 10B, the chip 20A, and the chip 20B), so the process of the bump pads and the bump structures may be omitted, which in turn improves the cost and the cycle time of the semiconductor package deice, and enhances the performance of the semiconductor package device.

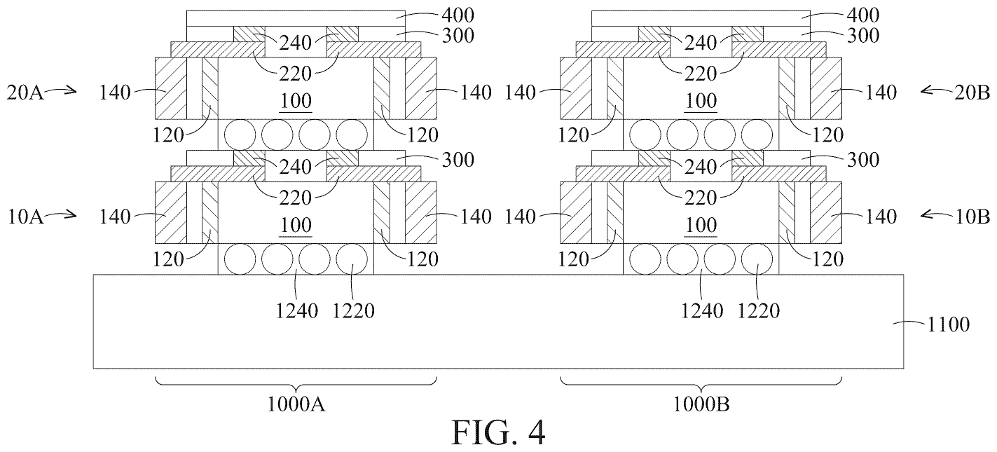

Referring to FIG. 4, a carrier 1100 may be provided, and the chip 10A, the chip 10B, the chip 20A, and the chip 20B may be stacked on the carrier 1100. The chip 10A and the chip 20A may be sequentially stacked on the carrier 1100 to become a chip stack 1000A, while the chip 10B and the chip 20B may be sequentially stacked on the carrier 1100 to become a chip stack 1000B. Although the chip stack 1000A and the chip stack 1000B are illustrated and each has two chips, any quantity of the chip stacks may be carried on the carrier 1100, and every chip stack may have any quantity of chips, as long as the topmost chip of every chip stack is additionally designed to have the dielectric layer 400. The conventional bump pads and bump structures are replaced with an adhesive layer 1200. The chip 10A of the chip stack 1000A and the chip 10B of the chip stack 1000B may be attached to the surface of the carrier 1100 through the adhesive layer 1200, while the chip 20A of the chip stack 1000A and the chip 20B of the chip stack 1000B may be attached onto the top surfaces of the chip 10A and the chip 10B, respectively. In comparison with the bump pads and the bump structures, using the adhesive layer 1200 may simplify the process. The adhesive layer 1200 may include a supporting structure 1220 and a glue layer 1240.

Still referring to FIG. 4, the carrier 1100 may include insulation materials without any circuitry. The carrier 1100 may only be used to carry the chip stack 1000A and the chip stack 1000B. The carrier 1100 may be a laminate plate. For example, the carrier 1100 may include multiple metal layers and multiple dielectric layers alternately arranged therein, and multiple vias may be formed through the dielectric layers to couple the metal layers, allowing the underlying metal layer to be electrically connected to the overlying metal layer. The thickness of the carrier 1100 may be between 50 μm and 200 μm.

Referring to FIG. 4, the adhesive layer 1200 may be vertically located between the carrier 1100 and the chip 10A, between the carrier 1100 and the chip 10B, between the chip 10A and the chip 20A, and between the chip 10B and the chip 20B. The supporting structure 1220 of the adhesive layer 1200 may include spacer paste, while the glue layer 1240 of the adhesive layer 1200 may include die attach film (DAF). The supporting structure 1220 of the adhesive layer 1200 supports and maintains the space between the carrier 1100 and the chips, or the space between chips, while the glue layer 1240 of the adhesive layer 1200 ensures the adhesion between the carrier 1100 and the chips, or the adhesion between chips. In other words, the adhesive layer 1200 may ensure that the chip 10A, the chip 10B, the chip 20A, and the chip 20B all have uniform heights. If the adhesive layer 1200 does not include the supporting structure 1220, then the stacked chips may easily generate height variation. Materials of the supporting structure 1220 of the adhesive layer 1200 may include glass fiber, silica, the like, or a combination thereof. Materials of the glue layer 1240 of the adhesive layer 1200 may include epoxy resin, hardeners, the like, or a combination thereof. The adhesive layer 1200 may be formed by dispensing or spin-on coating.

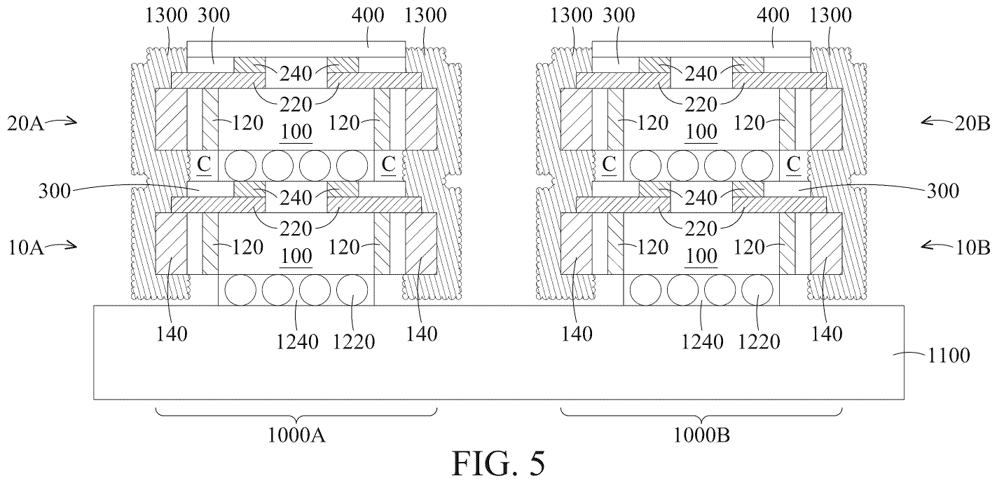

Referring to FIG. 5, a conductive layer 1300 may be formed on the exposed surfaces of the through silicon vias 140 on the sidewalls of each of the chip 10A, the chip 10B, the chip 20A, and the chip 20B. The conductive layer 1300 may be expanded continuously in a vertical direction. Therefore, the conductive layer 1300 may extend from the exposed surfaces of the through silicon vias 140 of the chip 10A to the exposed surfaces of the through silicon vias 140 of the chip 20A, and the conductive layer 1300 may extend from the exposed surfaces of the through silicon vias 140 of the chip 10B to the exposed surfaces of the through silicon vias 140 of the chip 20B. The conductive layer 1300 may electrically connect the chip 10A and the chip 20A of the chip stack 1000A, and may electrically connect the chip 10B and the chip 20B of the chip stack 1000B. From another perspective, the conductive layer 1300 may be considered as wire bonding, which bonds the exposed surfaces of the through silicon vias 140 of the overlying chip and the underlying chip of the chip stack. The thickness of the conductive layer 1300 may be between 10 μm and 20 μm. Materials and the formation of the conductive layer 1300 may be similar to those of the seal ring structures 120. The conductive layer 1300 may be formed by electroless plating, and may be formed with nickel palladium gold (NiPdAu) or nickel gold (NiAu). Because nickel has superior corrosion resistance, nickel may serve as a protection layer to enhance the corrosion resistance of gold.

According to some embodiments of the present disclosure, the exposed surfaces of the through silicon vias 140 may serve as a medium (including copper), so the chemical replacement (that is the oxidation reduction reaction) may be carried out to grow nickel palladium gold or nickel gold. Different from what is commonly known, the semiconductor package device 1000 of the present disclosure intentionally allow the metal material on the through silicon vias 140 of the overlying chip and the underling chip to come in contact with each other, so the chip stack may be conducting to establish the electrical connection. Since the through silicon vias 140 are located on the sidewalls of the chip 10A, the chip 10B, the chip 20A, and the chip 20B, the relatively low precision and reliability of the deposited metal layer would not affect the performance of the semiconductor package device 1000.

In order to more effectively expand the conductive layer 1300 in the vertical direction, the upper surface and the lower surface of every through silicon via 140 may be completely exposed. Therefore, the metal material of the conductive layer 1300 may be expanded upward and downward from the upper surface and the lower surface of each through silicon via 140, respectively. Furthermore, in order to prevent the metal material of the conductive layer 1300 from inadvertently growing onto the exposed metal surface of the bonding pads 240, it is necessary to ensure the bonding pads 240 of the intermediate chips of the chip stack 1000A and the chip stack 1000B are covered by the adhesive layer 1200, and it is necessary to ensure the bonding pads 240 of the topmost chips of the chip stack 1000A and the chip stack 1000B are covered by the dielectric layer 400. After the formation of the conductive layer 1300, cavities C may be defined between the chip 10A and the chip 20A, and between the chip 10B and the chip 20B. Alternatively, the growth of the conductive layer 1300 may completely fill the cavities C.

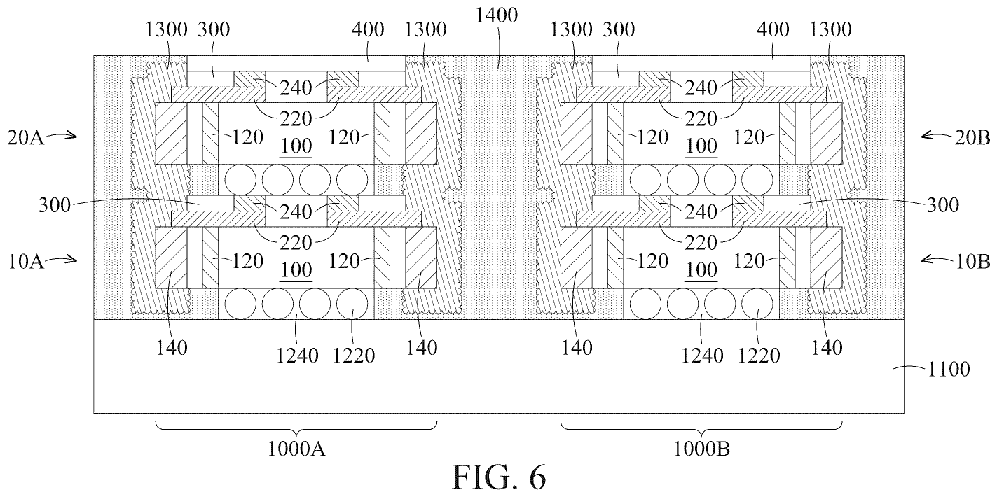

Referring to FIG. 6, a molding compound 1400 may be formed on the carrier 1100. The molding compound 1400 may cover the chip stack 1000A and the chip stack 1000B, and may fill the cavities C (if existed). It should be appreciated that the structures of the chip stack 1000A and the chip stack 1000B themselves are very fragile. The molding compound 1400 may protect the chip stack 1000A and the chip stack 1000B from the impact of the mechanical stress, for subsequent operations. Furthermore, the molding compound 1400 may expose the top surface of the dielectric layer 400 by the planarization process. After the planarization process, the top surface of the dielectric layer 400 may be leveled with the top surface of the molding compound 1400, and the molding compound 1400 may laterally surround the chip stack 1000A and the chip stack 1000B (including the chip 10A, the chip 10B, the chip 20A, and the chip 20B). The molding compound 1400 may be formed using hot embossing, compression, or injection methods. The height of the molding compound 1400 may be between 0.5 mm and 1.5 mm. Generally, materials of the molding compound 1400 may be plastic composites, which may include epoxy resins, phenolic hardened materials, silica, catalyst, pigment, or mold release agents.

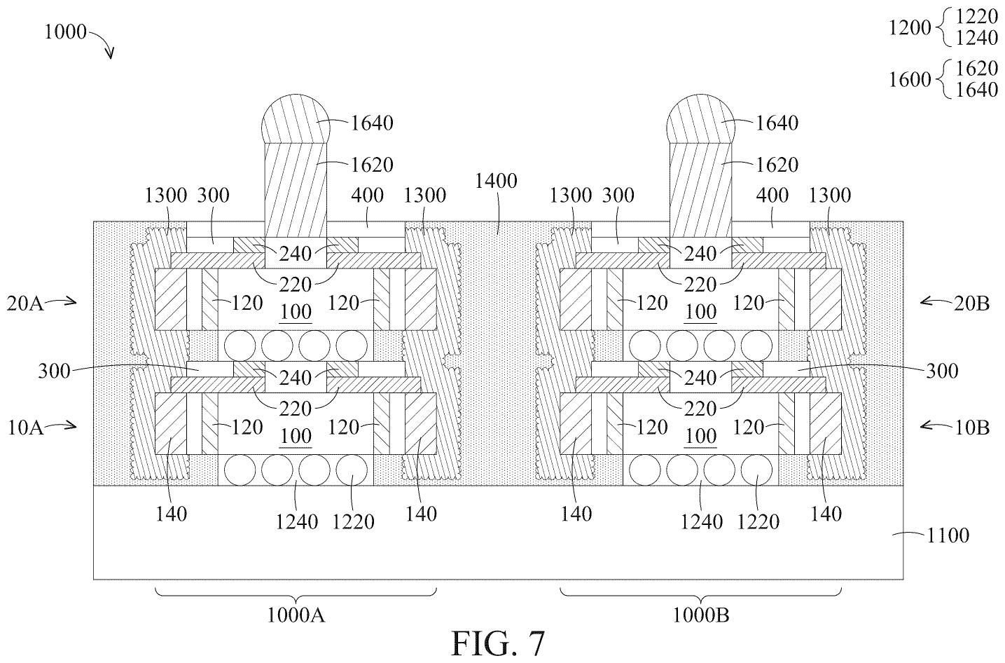

Referring to FIG. 7, bump structures 1600 may be formed on the chip stack 1000A and the chip stack 1000B. The bump structures 1600 are disposed through the dielectric layer 400, and may be used to connect the semiconductor package device 1000 to other components (such as the printed circuit board). The bump structures 1600 may be connected to the bonding pads 240 through the dielectric layer 400. It should be appreciated that the quantity of the bump structures 1600 and the quantity of the bonding pads 240 are not related. Although only one bump structure 1600 is illustrated on each of the chip stack 1000A and the chip stack 1000B, but the present disclosure is not limited thereto. For example, any quantity of the bump structures 1600 may be disposed on each of the chip stack 1000A and the chip stack 1000B. The horizontal dimension of the bump structures 1600 may be between 80 μm×80 μm and 400 μm×400 μm, for example, having a design of 250 μm×250 μm. The bump structures 1600 may include pillar structures 1620 and solder balls 1640.

The pillar structures 1620 may be formed through the dielectric layer 400, and may sit on the passivation layer 300. The pillar structures 1620 may be connected to the bonding pads 240 through the dielectric layer 400. The pillar structures 1620 may be conductive elements, which connect the chip stack 1000A/the chip stack 1000B to the subsequently formed solder balls 1640. The pillar structures 1620 may be formed into any suitable geometric shapes from a top view. Due to the application and the design requirements, the pillar structures 1620 may have straight sidewalls or slanted sidewalls. Materials of the pillar structures 1620 may include any suitable metals or alloys mentioned above, such as copper, copper nickel gold alloy, the like, or a combination thereof. The pillar structures 1620 may be formed by any suitable process (such as plating or the like).

The solder balls 1640 may be disposed on the pillar structures 1620, and may be used to connect the semiconductor package device 1000 to other components. Materials of the solder balls 1640 may include any suitable metals mentioned above, such as tin, gold, silver, lead, the like, a combination thereof, or an alloy thereof. The solder balls 1640 may be thermally bonded onto the pillar structures 1620 using a bonding equipment, followed by a reflow process.

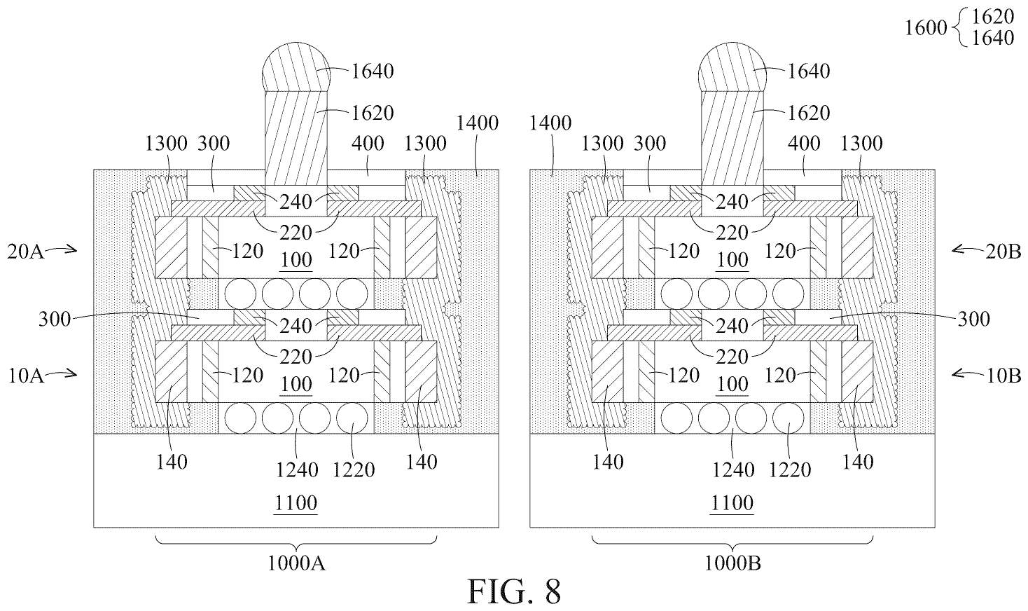

Referring to FIG. 8, the singulation process may be performed on the semiconductor package device 1000. The chip stack 1000A and the chip stack 1000B may be severed by any suitable process mentioned above (not limited to plasma dicing). Every singulated package chip has a single chip stack. Using the alignment detection method, it can be ensured that the dicing streets for the singulation process are positioned away from important elements of the semiconductor package device 1000 (for example, the chip stack 1000A and the chip stack 1000B). In the embodiments that use the dicing streets, the width of the dicing streets may be between 80 μm and 100 μm.

The singulated chip stack 1000A and the chip stack 1000B may be used to carry out subsequent processes. It should be appreciated that the suitable package processes may be performed before or after performing the singulation process. The suitable types of the package processes may include wafer level chip scale package (WLCSP), transistor outline (TO), small outline integrated circuit (SOIC), quad flat package (QFP), dual flat non-leaded (DFN), quad flat non-leaded (QFN), or ball grid array (BGA).

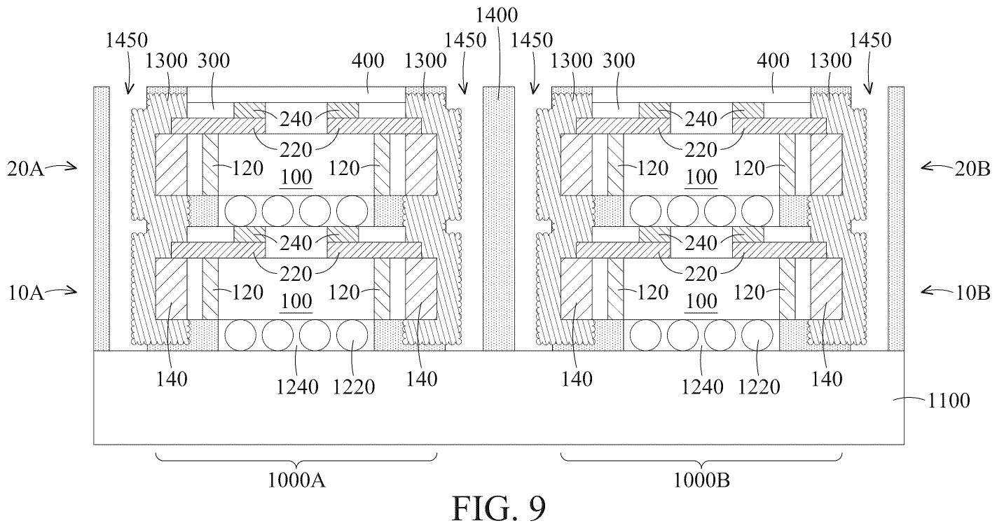

FIGS. 9-11 illustrate cross-sectional views of various intermediate stages of forming a semiconductor package device 1000′. In comparison with the semiconductor package device 1000, the semiconductor package device 1000′ includes the formation of a conductive layer 1500 in the molding compound 1400. The features of the chip stack 1000A (including the chip 10A and the chip 20A), the chip stack 1000B (including the chip 10B and the chip 20B), the carrier 1100, the adhesive layer 1200 (including the supporting structure 1220 and the glue layer 1240), the conductive layer 1300, the molding compound 1400, and the bump structures 1600 (including the pillar structures 1620 and the solder balls 1640) are similar to those illustrated in FIG. 8, and the details are not described again herein to avoid repetition.

Referring to FIG. 9, in comparison with FIG. 6, openings 1450 may be further formed into the molding compound 1400. For simplicity, the procedures of FIGS. 1-5 are omitted. The openings 1450 may be filled with the conductive layer 1500 during the subsequent process. It should be appreciated that it is necessary for the conductive layer 1500 to physically contact the conductive layer 1300. Therefore, the openings 1450 may penetrate through the entire molding compound 1400 to expose the surface of the carrier 1100, which in turn ensures the conductive layer 1500 may effectively come in physical contact with the conductive layer 1300. The horizontal dimension of the openings 1450 may be between 60 μm and 150 μm. In order to ensure the conductive layer 1500 and the conductive layer 1300 are in physical contact, it is necessary for the openings 1450 to expose the conductive layer 1300, but without significantly causing damage to the conductive layer 1300. Therefore, the selective plasma dicing and the mask similar to those used in FIG. 3 may be implemented to ensure the locations of the openings 1450 are accurate. In other words, the openings 1450 cut the material of the molding compound 1400 (for example, epoxy molding compound (EMC)) without substantially damaging the material of the conductive layer 1300 (for example, nickel palladium gold or nickel gold). More specifically, the portions of the conductive layer 1300 away from the through silicon vias 140 are exposed, while the portions of the conductive layer 1300 close to the through silicon vias 140 are still covered by the molding compound 1400.

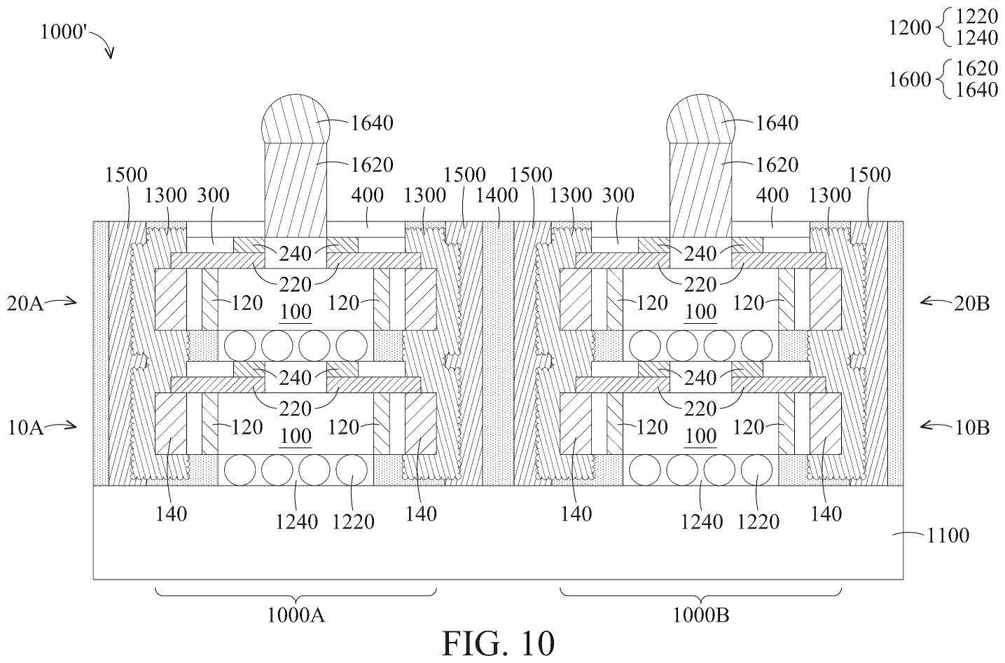

Referring to FIG. 10, the conductive layer 1500 may be formed in the openings 1450. From another perspective, the conductive layer 1500 may be formed through the molding compound 1400. The conductive layer 1500 physically contacts the conductive layer 1300. The configuration of the conductive layer 1500 may further enhance the electrical connection between the chip 10A and the chip 20A, and the electrical connection between the chip 10B and the chip 20B. As mentioned previously, the growth of the conductive layer 1300 using electroless plating is difficult to control, thus the thickness of the conductive layer 1300 may be too large or too small. If the thickness of the conductive layer 1300 is too small, the resulting impedance of the semiconductor package device during operation may be too large. Therefore, the conductive layer 1500 may improve the potential impedance of the semiconductor package device during operation. Since the conductive layer 1500 may adapt the entire profile of the openings 1450, the dimension of the conductive layer 1500 may be similar to that of the openings 1450. Materials and the formation of the conductive layer 1300 may be similar to those of the seal ring structures 120, and the details are not described again herein to avoid repetition. The materials of the conductive layer 1500 may also adopt silver epoxy. The deposition of metal materials and the deposition of silver epoxy may have different throughputs. In comparison with metal materials, filling the openings 1450 with silver epoxy may consume shorter process time. Furthermore, the planarization process may be performed so the top surface of the molding compound 1400 may be leveled with the top surface of the conductive layer 1500.

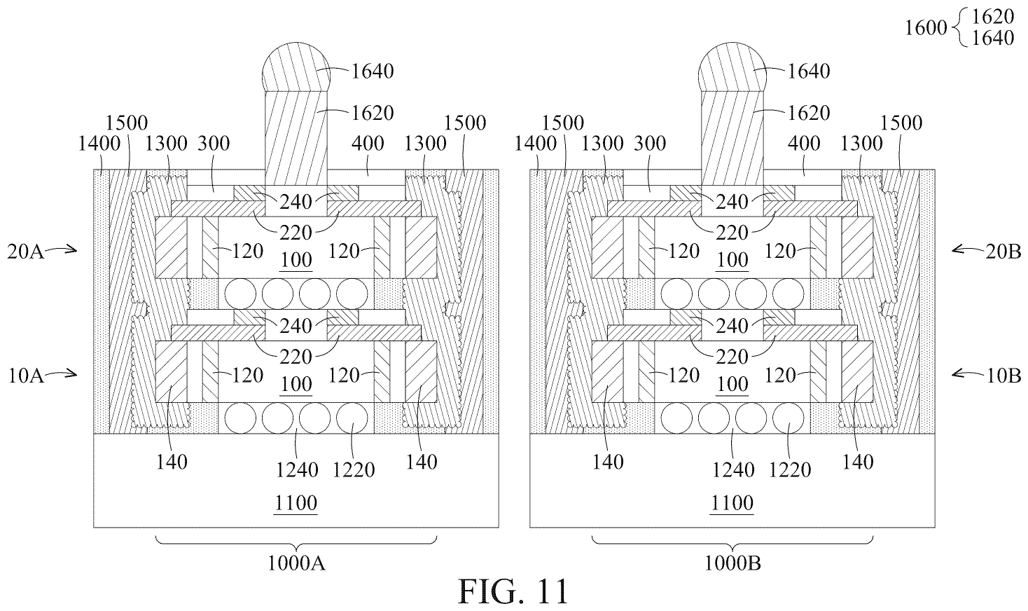

Referring to FIG. 11, in comparison with FIG. 8, the singulation process may be performed on the semiconductor package device 1000′ to sever the chip stack 1000A and the chip stack 1000B. For simplicity, the procedure of FIG. 7 is omitted. Using the alignment detection method, it can be ensured that the dicing streets (or the scribe lines) for the singulation process are positioned away from important elements of the semiconductor package device 1000′ (for example, the chip stack 1000A and the chip stack 1000B). In the embodiments that use the dicing streets, the width of the dicing streets may be between 80 μm and 100 μm. The singulated chip stack 1000A and the chip stack 1000B may be used to carry out the subsequent processes. The suitable package processes may be performed before or after performing the singulation process.

The semiconductor package device of the present disclosure includes the innovative design of the through silicon vias with the conductive layer. The through silicon vias of the conventional process may be disposed inside the circuit area of the chip, and the through silicon vias are coupled to the bump structures on the upper surface of the chip and the bump pads on the lower surface of the chip. Because the bump process may case the thinned substrate to generate warpage easily, thus the chip needs to be attached to a glass first, and the glass is stripped off subsequently. The combination of the bump structures and the bump pads, and the use of the glass all results in higher cost and longer cycle time of the overall manufacture process. The through silicon vias of the semiconductor package device of the present disclosure may be formed on the sidewalls of the chips, and the processes of the bump structures and the bump pads are omitted. This may release additional circuitry space of the chips, allowing more components to be integrated into the chips to increase the functional density. When the through silicon vias are configured on the sidewalls of the chips, the conductive material may be grown on the surface of the through silicon vias of every chip. As the growth duration progresses, the conductive material may be expanded in the vertical direction, which allows the conductive material on the through silicon vias of every chip to be adjoined with each other, and the electrical connection between the overlying chip and the underlying chip may be established. The cost and the cycle time of the semiconductor package device may be improved, and the performance of the semiconductor package device may be enhanced.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package device, comprising:
a carrier;
a first chip stack disposed on the carrier, comprising:
a first chip in contact with the carrier, wherein the first chip comprises a first through silicon via disposed on a sidewall of the first chip; and
a second chip disposed on the first chip, wherein the second chip comprises a second through silicon via disposed on a sidewall of the second chip; and
a first conductive layer extending from a surface of the first through silicon via to a surface of the second through silicon via, wherein the first conductive layer electrically connects the first chip to the second chip.

2. The semiconductor package device of claim 1, wherein the first chip further comprising:
a substrate; and
bonding pads disposed on the substrate.

3. The semiconductor package device of claim 2, wherein the first chip further comprising a seal ring structure embedded within the substrate.

4. The semiconductor package device of claim 3, wherein the seal ring structure is laterally located between the first through silicon via and the bonding pads.

5. The semiconductor package device of claim 4, wherein the first chip further comprising a wiring layer disposed between the substrate and the bonding pads.

6. The semiconductor package device of claim 5, wherein the wiring layer extends from below the bonding pads to above the first through silicon via.

7. The semiconductor package device of claim 6, wherein the wiring layer covers the seal ring structure.

8. The semiconductor package device of claim 1, wherein the second chip is attached on the first chip using an adhesive layer.

9. The semiconductor package device of claim 1, further comprising a molding compound disposed on the carrier and laterally surrounding the first chip stack.

10. The semiconductor package device of claim 9, further comprising a second conductive layer disposed through the molding compound and in physical contact with the first conductive layer.

11. The semiconductor package device of claim 1, further comprising a bump structure disposed on a top surface of the second chip.

12. A method of forming a semiconductor package device, comprising:
providing a first wafer, comprising:
a first substrate;
a first seal ring structure and a second seal ring structure embedded within the first substrate;
first bonding pads disposed on the first substrate, wherein the first seal ring structure laterally surrounds a first set of the first bonding pads, while the second seal ring structure laterally surrounds a second set of the first bonding pads; and
a first through silicon via and a second through silicon via embedded within the first substrate, wherein the first through silicon via and the second through silicon via are located outside the first seal ring structure and the second seal ring structure, respectively;
providing a second wafer, comprising:
a second substrate;
a third seal ring structure and a fourth seal ring structure embedded within the second substrate;
second bonding pads disposed on the second substrate, wherein the third seal ring structure laterally surrounds a first set of the second bonding pads, while the fourth seal ring structure laterally surrounds a second set of the second bonding pads;
a third through silicon via and a fourth through silicon via embedded within the second substrate, wherein the third through silicon via and the fourth through silicon via are located outside the third seal ring structure and the fourth seal ring structure, respectively; and
a dielectric layer covering the second bonding pads;
performing a singulation process on the first wafer to form a first chip and a second chip, wherein the first through silicon via and the second through silicon via are exposed from a sidewall of the first chip and a sidewall of the second chip, respectively;
performing the singulation process on the second wafer to form a third chip and a fourth chip, wherein the third through silicon via and the fourth through silicon via are exposed from a sidewall of the third chip and a sidewall of the fourth chip, respectively;
sequentially stacking the first chip and the third chip on a carrier;
sequentially stacking the second chip and the fourth chip on the carrier;
forming a first conductive layer to electrically connect the first through silicon via of the first chip to the third through silicon via of the third chip; and
forming a second conductive layer to electrically connect the second through silicon via of the second chip to the fourth through silicon via of the fourth chip.

13. The method of claim 12, wherein the first conductive layer and the second conductive layer are vertically extended from the first through silicon via to the third through silicon via and from the second through silicon via to the fourth through silicon via, respectively, by electroless plating.

14. The method of claim 12, further comprising forming an adhesive layer between the first chip and the third chip, and between the second chip and the fourth chip.

15. The method of claim 12, further comprising forming a molding compound on the carrier and laterally surrounding the first chip, the second chip, the third chip, and the fourth chip.

16. The method of claim 15, wherein openings are formed through the molding compound, wherein the openings expose the first conductive layer and the second conductive layer.

17. The method of claim 16, further comprising filling a third conductive layer and a fourth conductive layer into the openings to physically contact the first conductive layer and the second conductive layer, respectively.

18. The method of claim 12, further comprising thinning the first substrate of the first wafer and the second substrate of the second wafer before performing the singulation process on the first wafer and the second wafer.

19. The method of claim 18, wherein the first through silicon via and the second through silicon via are exposed from a bottom surface of the thinned first substrate, while the third through silicon via and the fourth through silicon via are exposed from a bottom surface of the thinned second substrate.

20. The method of claim 12, further comprising forming a first bump structure and a second bump structure respectively on a top surface of the third chip and a top surface of the fourth chip, wherein the first bump structure and the second bump structure penetrate through the dielectric layer.
